(19) United States
(12) Patent Application Publication
(10) Pub. No.: US 2025/0308930 A1
(43) Pub. Date: Oct. 2, 2025

(54) METHOD OF MANUFACTURING SEMICONDUCTOR DEVICE

(71) Applicant: FUJI ELECTRIC CO., LTD., Kawasaki-shi (JP)

(72) Inventor: Ryota KATAOKA, Matsumoto-city (JP)

(73) Assignee: FUJI ELECTRIC CO., LTD., Kawasaki-shi (JP)

(21) Appl. No.: 19/065,058

(22) Filed: Feb. 27, 2025

(30) Foreign Application Priority Data
Apr. 2, 2024 (JP) 2024-059377

(51) Int. Cl. H01L 21/3213; H01L 21/768; H10D 84/01

(52) U.S. Cl. CPC H01L 21/32134; H01L 21/32139; H01L 21/76892; H10D 84/0107

(57) ABSTRACT

A method of manufacturing a semiconductor device, including: forming a first electrode film at a surface of a semiconductor wafer, the first electrode film having a convex defect at a surface thereof; covering the surface of the first electrode film with a resist film and inducing a break in the resist film at a portion corresponding to the convex defect, thereby generating a resist defect portion from which the convex defect is exposed; etching the convex defect exposed from the resist defect portion; removing the resist film after the etching; forming a second electrode film at the surface of the first electrode film after the removal of the resist film, thereby forming a surface electrode constituted by the first electrode film and the second electrode film; and patterning the surface electrode.

### CROSS REFERENCE TO RELATED APPLICATIONS

This application is based upon and claims the benefit of priority of the prior Japanese Patent Application No. 2024-059377, filed on Apr. 2, 2024, the entire contents of which are incorporated herein by reference.

### BACKGROUND OF THE INVENTION

### 1. Field of the Invention

Embodiments of the present disclosure relate to a method of manufacturing a semiconductor device.

### 2. Description of the Related Art

Electrodes of semiconductor devices are commonly known to be formed by an aluminum (Al) film and a nickel (Ni) film for bonding solder covering the aluminum film (for example, refer to Japanese Laid-Open Patent Publication No. 2018-060885).

### SUMMARY OF THE INVENTION

According to an embodiment of the present disclosure, a method of manufacturing a semiconductor device includes: forming a first electrode film at a surface of a semiconductor wafer, the first electrode film having a convex defect at a surface thereof; covering the surface of the first electrode film with a resist film and inducing a break in the resist film at a portion corresponding to the convex defect, thereby generating a resist defect portion from which the convex defect is exposed; etching the convex defect exposed from the resist defect portion; removing the resist film after the etching; forming a second electrode film at the surface of the first electrode film after the removal of the resist film, thereby forming a surface electrode constituted by the first electrode film and the second electrode film; and patterning the surface electrode.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a flowchart depicting an outline of a method of manufacturing a semiconductor device according to an embodiment.

FIG. 2 is a plan view depicting a state when a semiconductor wafer is viewed from a front surface thereof.

FIG. 3 is a cross-sectional view depicting a state of the semiconductor device according to the embodiment during manufacture.

FIG. 4 is a cross-sectional view depicting a state of the semiconductor device according to the embodiment during manufacture.

FIG. 5 is a cross-sectional view depicting a state of the semiconductor device according to the embodiment during manufacture.

FIG. 6A is a cross-sectional view depicting a state of the semiconductor device according to the embodiment during manufacture.

FIG. 6B is a cross-sectional view depicting a state of the semiconductor device according to the embodiment during manufacture.

FIG. 6C is a cross-sectional view depicting a state of the semiconductor device according to the embodiment during manufacture.

FIG. 7A is a cross-sectional view depicting a state of the semiconductor device according to the embodiment during manufacture.

FIG. 7B is a cross-sectional view depicting a state of the semiconductor device according to the embodiment during manufacture.

FIG. 8A is a cross-sectional view depicting a state of the semiconductor device according to the embodiment during manufacture.

FIG. 8B is a cross-sectional view depicting a state of the semiconductor device according to the embodiment during manufacture.

FIG. 9 is a cross-sectional view depicting another state of the semiconductor device according to the embodiment during manufacture.

FIG. 10 is a cross-sectional view depicting another state of the semiconductor device according to the embodiment during manufacture.

FIG. 11 is a cross-sectional view depicting another state of the semiconductor device according to the embodiment during manufacture.

FIG. 12 is a cross-sectional view depicting another state of the semiconductor device according to the embodiment during manufacture.

FIG. 13 is a cross-sectional view depicting another state of the semiconductor device according to the embodiment during manufacture.

FIG. 14 is a cross-sectional view depicting another state of the semiconductor device according to the embodiment during manufacture.

FIG. 15 is a cross-sectional view depicting a state of the semiconductor device according to the embodiment during manufacture.

FIG. 16 is a cross-sectional view depicting a state of the semiconductor device according to the embodiment during manufacture.

FIG. 17 is a cross-sectional view schematically depicting a state of the semiconductor device of the reference example during manufacture.

FIG. 18 is a cross-sectional view schematically depicting a state of the semiconductor device of the reference example during manufacture.

FIG. 19A is a table of cross-sectional views schematically depicting states of surface electrodes of an example and the reference example during formation.

FIG. 19B is a table of cross-sectional views schematically depicting states of surface electrodes of the example and the reference example during formation.

FIG. 19C is a table of cross-sectional views schematically depicting states of surface electrodes of the example and the reference example during formation.

FIG. 20 is a cross-sectional view depicting an example of the structure of the semiconductor device manufactured according to the method of manufacturing the semiconductor device according to the embodiments.

FIG. 21 is a characteristics diagram showing experimental results for a relationship between resist film thickness and the concave defect change rate of convex defects of the surface of the first electrode film.

FIG. 22 is a characteristics diagram showing experimental results for the relationship between resist film thickness and the concave defect change rate of convex defects of the surface of the first electrode film.

FIG. 23 is a characteristics diagram showing experimental results for the relationship between resist film thickness and the concave defect change rate of convex defects of the surface of the first electrode film.

FIG. 24 is a cross-sectional view schematically depicting a state (non-conforming) of the semiconductor device of the reference example during manufacture.

FIG. 25 is a cross-sectional view schematically depicting a state (non-conforming) of the semiconductor device of the reference example during manufacture.

FIG. 26A is a cross-sectional view schematically depicting a state (non-conforming) of the semiconductor device of the reference example during manufacture.

FIG. 26B is a cross-sectional view schematically depicting a state (non-conforming) of the semiconductor device of the reference example during manufacture.

FIG. 27A is a cross-sectional view schematically depicting a state (non-conforming) of the semiconductor device of the reference example during manufacture.

FIG. 27B is a cross-sectional view schematically depicting a state (non-conforming) of the semiconductor device of the reference example during manufacture.

FIG. 27C is a cross-sectional view schematically depicting a state (non-conforming) of the semiconductor device of the reference example during manufacture.

FIG. 28 is a cross-sectional view schematically depicting a state (conforming) of the semiconductor device of the reference example during manufacture.

FIG. 29 is a cross-sectional view schematically depicting a state (conforming) of the semiconductor device of the reference example during manufacture.

FIG. 30 is a cross-sectional view schematically depicting a state (conforming) of the semiconductor device of the reference example during manufacture.

FIG. 31 is a cross-sectional view schematically depicting a state (conforming) of the semiconductor device of the reference example during manufacture.

### DETAILED DESCRIPTION OF THE INVENTION

First, problems associated with the conventional techniques are discussed. When foreign matter is attached to a surface of a semiconductor substrate, the aluminum film is formed covering the foreign matter, whereby the foreign matter causes a convex defect to occur in the aluminum film. Near the convex defect, coverage of the aluminum film is poor and a slit (gap) is formed in the aluminum film. Further, a resist mask used during patterning of the aluminum film is interrupted by (has a break at) the convex defect and a concave defect that penetrates through the aluminum film in a depth direction is formed in a resist defect portion. These metal defects (slits, concave defects) of the aluminum film cause defects of the semiconductor device.

An outline of an embodiment of the present disclosure is described. (1) A method of manufacturing a semiconductor device according to one embodiment of the present disclosure includes the following. A first process of forming a first electrode film at a surface of a semiconductor wafer. A second process of covering a surface of the first electrode film with a resist film and inducing a break in the resist film at a portion corresponding to a convex defect of the surface of the first electrode film and thereby generating a resist defect portion. A third process of etching the convex defect exposed in the resist defect portion. A fourth process of removing the resist film after the third process. A fifth process of forming a second electrode film at the surface of the first electrode film after the fourth process and thereby forming a surface electrode constituted by the first electrode film and the second electrode film. A sixth process of patterning the surface electrode.

According to the disclosure above, a height position of the surface of a portion of the first electrode film exposed in the resist defect portion may be lowered during the third process and thus, no convex defect occurs at the surface of the second electrode film (surface of the surface electrode). A concave defect (metal defect) that occurs in the first electrode film may be covered by the second electrode film. No convex defect occurs at the surface of the surface electrode, whereby an occurrence of concave defects in the surface electrode during patterning of the surface electrode may be reduced and the rate of conforming semiconductor devices may be enhanced.
(2) Further, in the method of manufacturing the semiconductor device according to the present disclosure, in (1) above, in the third process, the convex defect may be converted into a concave defect.

According to the disclosure above, during the third process, the height position of the surface of the portion of the first electrode film exposed in the resist defect portion may be made lower than a height position of a flat portion of the surface of the first electrode film.
(3) Further, in the method of manufacturing the semiconductor device according to the present disclosure, in (1) or (2) above, in the third process, the convex defect may be converted into a convex portion having a height that is lower than a height of the convex defect.

According to the disclosure above, during the third process, the height position of the surface of the portion of the first electrode film exposed in the resist defect portion may made to approach the height position of a flat portion of the surface of the first electrode film.
(4) Further, in the method of manufacturing the semiconductor device according to the present disclosure, in any one of (1) to (3) above, a thickness of the resist film may be in a range of 2.6 μm to 3.2 μm.

According to the disclosure above, during the third process, a rate (the concave defect change rate) that the convex defect of the surface of the first electrode film is converted into a concave defect may be increased.
(5) Further, in the method of manufacturing the semiconductor device according to the present disclosure, in (4) above, the thickness of the resist film may be not more than 3.0 μm.

According to the disclosure above, during the third process, the rate (the concave defect change rate) that the convex defect of the surface of the first electrode film is converted into a concave defect may be further increased.
(6) Further, in the method of manufacturing the semiconductor device according to the present disclosure, in any one of (1) to (5) above, a height from a flat portion of the surface of the first electrode film to a top of the convex defect may be 4 μm or more.

According to the disclosure above, during the second process, the resist defect portion may be reliably generated in the resist film at a portion corresponding to the convex defect of the surface of the first electrode film.
(7) Further, in the method of manufacturing the semiconductor device according to the present disclosure, in any one of (1) to (6) above, the thickness of the first electrode film may be in a range of 25% to 75% of the thickness of the surface electrode.

According to the disclosure above, during the first process, a convex defect is generated at the surface of the first electrode film and during the fifth process, the occurrence of a convex defect at the surface of the second electrode film, caused by unevenness of a lower layer (unevenness of the surface of the first electrode film) may be prevented.
(8) Further, in the method of manufacturing the semiconductor device according to the present disclosure, in (7) above, the thickness of the first electrode film may be 50% of the thickness of the surface electrode.

According to the disclosure above, the thicknesses of the first and second electrode films become equal and thus, it becomes easy to achieve both generation of a convex defect at the surface of the first electrode film during the first process and prevention of an occurrence of a convex defect at the surface of the second electrode film during the fifth process (the convex defect being caused by unevenness of a lower layer (unevenness of the surface of the first electrode film)).
9) Further, in the method of manufacturing the semiconductor device according to the present disclosure, in any one of (1) to (8) above, the thickness of the surface electrode may be in a range of 4 μm to 6 μm.

According to the disclosure above, the surface electrode may be formed without changing design conditions (product thickness), etc. and thus, variation of characteristics of the semiconductor device may be prevented.
(10) Further, in the method of manufacturing the semiconductor device according to the present disclosure, in any one of (1) to (9) above, the surface electrode may contain aluminum as a main constituent.

According to the disclosure above, the surface electrode may be formed without changing the design conditions (material), etc. and thus, variation of characteristics of the semiconductor device may be prevented.
(11) Further, in the method of manufacturing the semiconductor device according to the present disclosure, in any one of (1) to (10) above, in the third process, the etching may be wet etching.

According to the disclosure above, during the third process, the convex defect at the surface of the first electrode film may be etched having a substantially uniform thickness.

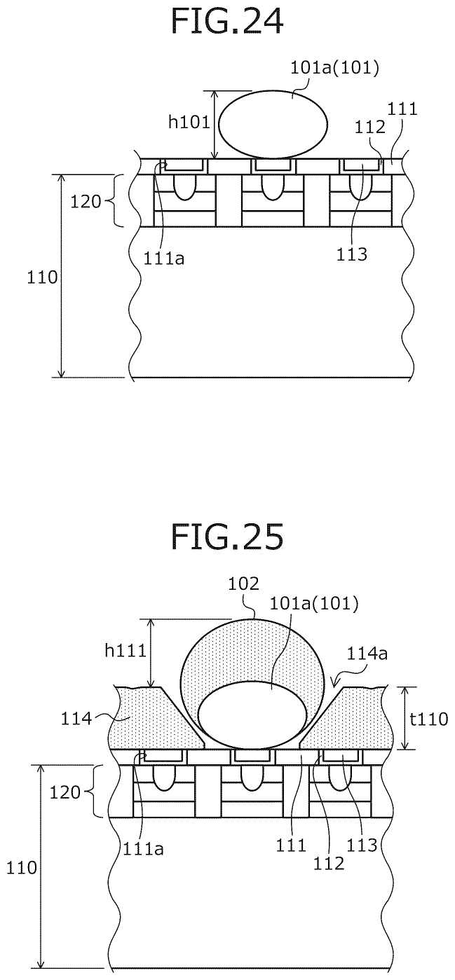

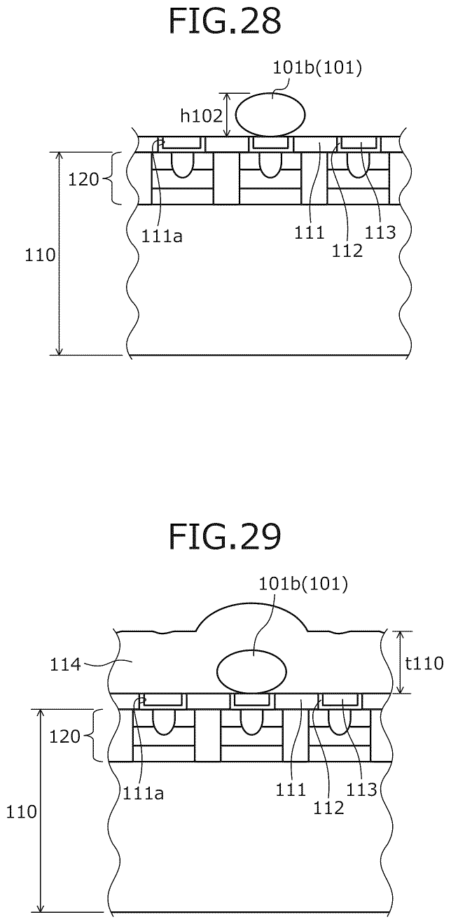

Findings underlying the present disclosure are discussed. First, a method of manufacturing a semiconductor device of a reference example is described. FIGS. 24, 25, 26A, 26B, 27A, 27B, and 27C are cross-sectional views schematically depicting states (non-conforming) of the semiconductor device of the reference example during manufacture. FIGS. 28, 29, 30, and 31 are cross-sectional views schematically depicting states (conforming) of the semiconductor device of the reference example during manufacture. In the method of manufacturing the semiconductor device of the reference example, a convex defect 102 occurs at a surface of a surface electrode 114 of the semiconductor device, the convex defect 102 being caused by foreign matter 101 originating at a previous stage (FIGS. 24, 25, 28, and 29). For example, when an opening width of contact holes 111a of an interlayer insulating film 111 is narrow, before formation of the surface electrode 114, which primarily contains aluminum (Al), a conductive film such as a tungsten (W) film is embedded in the contact holes 111a via a barrier metal 112 by a chemical vapor deposition (CVD) method, thereby forming contact plugs 113, whereby electrode embeddability is enhanced.

In this instance, after the conductive film constituting the contact plugs 113 is etched and unnecessary portions are removed, the foreign matter 101 adheres to a front surface (surface of the interlayer insulating film 111, surfaces of each of the contact plugs 113) of a semiconductor wafer 110 (FIGS. 24 and 28). In a state with the foreign matter 101 adhered to the front surface of the semiconductor wafer 110, when the surface electrode 114 is formed having a product thickness t110 (for example, about 5 μm), the foreign matter 101 (101a and 101b) becomes entrapped in the surface electrode 114 (FIGS. 25 and 29).

The surface electrode 114 bulges at a portion where the relatively large foreign matter 101a is entrapped, whereby a convex defect 102 occurs at the surface of the surface electrode 114. In a vicinity of the convex defect 102, coverage of the surface electrode 114 degrades and a slit (gap) 114a occurs in the surface electrode 114 (FIG. 25). A convex portion (hereinafter, base convex portion, not depicted) with a relatively high height formed at a surface of a lower layer of the surface electrode 114 further causes the convex defect 102 occurring at the surface of the surface electrode 114.

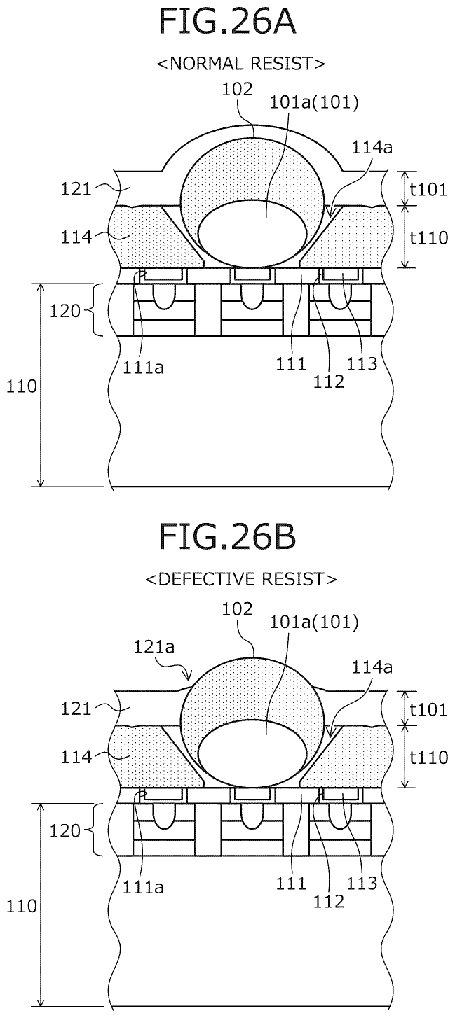

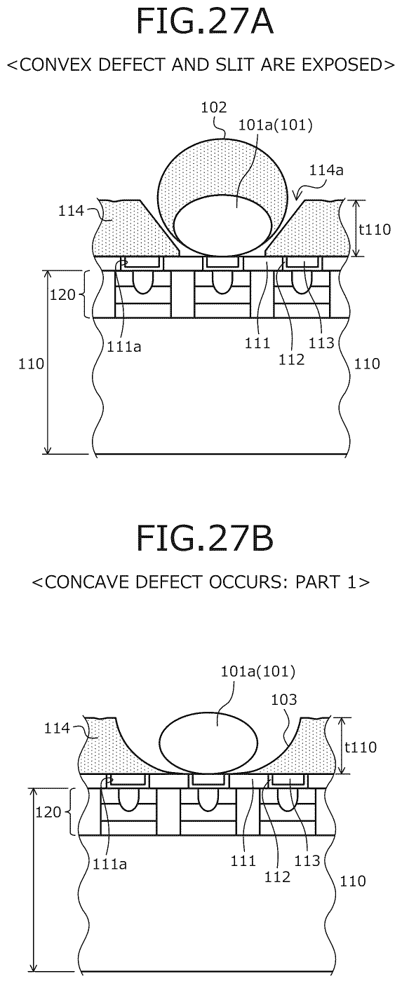

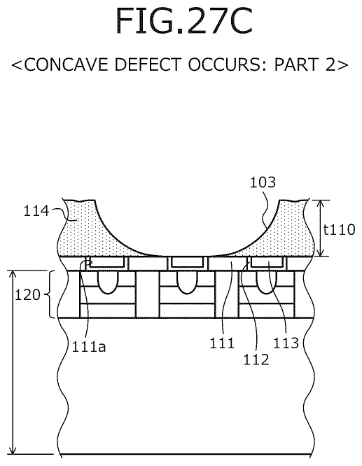

Further, a thickness t101 of a resist film 121 used as a mask during patterning of the surface electrode 114 is, for example, about 3.2 μm; the resist film 121 is interrupted (has a break) at a portion that corresponds to the convex defect 102 (FIG. 26B) and the convex defect 102 is etched at a resist defect portion 121a, whereby a concave defect 103 occurs (FIGS. 27B and 27C). The concave defect 103 penetrates through the surface electrode 114 in the depth direction. Thus, regardless of whether the foreign matter 101a remains within the concave defect 103, in subsequent testing and assembly processes, for example, during a plating treatment for forming a nickel (Ni) film for solder bonding, plating solution may penetrate into the lower layer through the concave defect 103, causing element destruction due to the nickel film being eaten into, or in a case of a MOS gate (insulated gate with a three-layer structure of metal-oxide-semiconductor), diffusion of sodium (Na) ions in the plating solution may cause fluctuations in gate characteristics, resulting in a non-conforming semiconductor device (semiconductor chip).

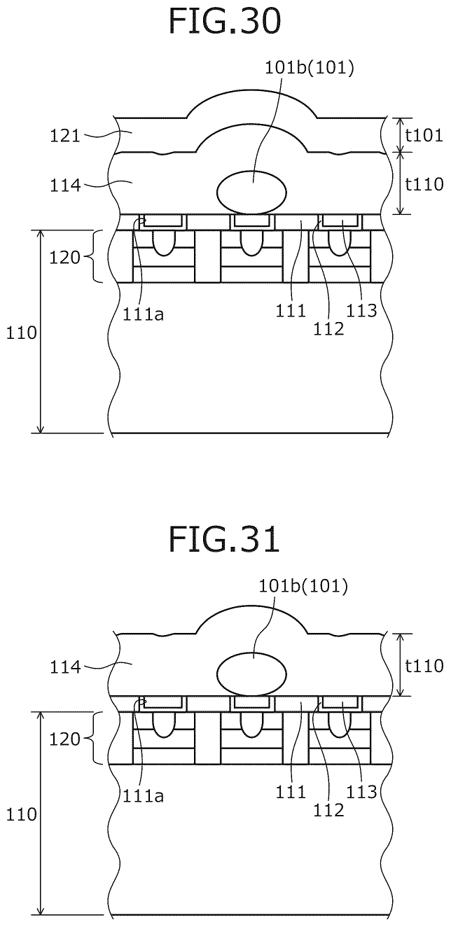

Even when the convex defect 102 is completely covered by the resist film 121 (FIG. 26A), after the resist film 121 is removed, the convex defect 102 and a slit 114a are exposed at the surface electrode 114 (FIG. 27A) and thus, during the plating treatment to the surface of the surface electrode 114, the plating solution penetrates to the lower layer from the slit 114a, resulting in the semiconductor device being non-conforming. On the other hand, the foreign matter 101b of a relatively small size is buried inside the surface electrode 114 and does not cause the convex defect 102 to occur and thus, the slit 114a in the surface electrode 114 and the resist defect portion 121a of the resist film 121 do not occur (FIGS. 29 and 30). Thus, the described factors causing non-conforming do not occur and the semiconductor device is judged to be conforming with the foreign matter 101b of a relatively small size being buried inside the surface electrode 114 (FIG. 31). Thus, in the present embodiment, metal defects (slits, concave defects) of the surface electrode are reduced and the conforming rate of the product (semiconductor device) is enhanced.

Embodiments of a method of manufacturing a semiconductor device according to the present disclosure is described in detail with reference to the accompanying drawings. In the present description and accompanying drawings, layers and regions prefixed with n or p mean that majority carriers are electrons or holes. Additionally, +or −appended to n or p means that the impurity concentration is higher or lower, respectively, than layers and regions without +or −. In the description of the embodiments below and the accompanying drawings, main portions that are identical are given the same reference numerals and are not repeatedly described. Further, in the present description, when Miller indices are described, “−” means a bar added to an index immediately after the “−”, and a negative index is expressed by prefixing “−” to the index.

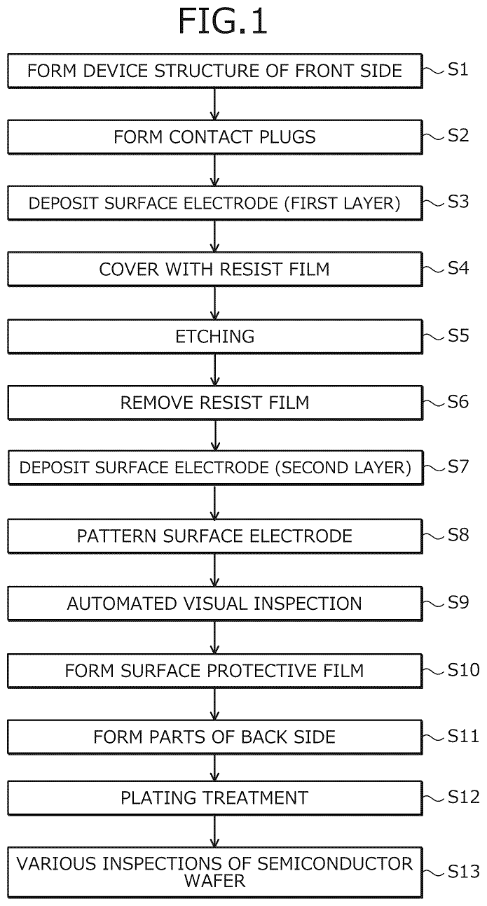

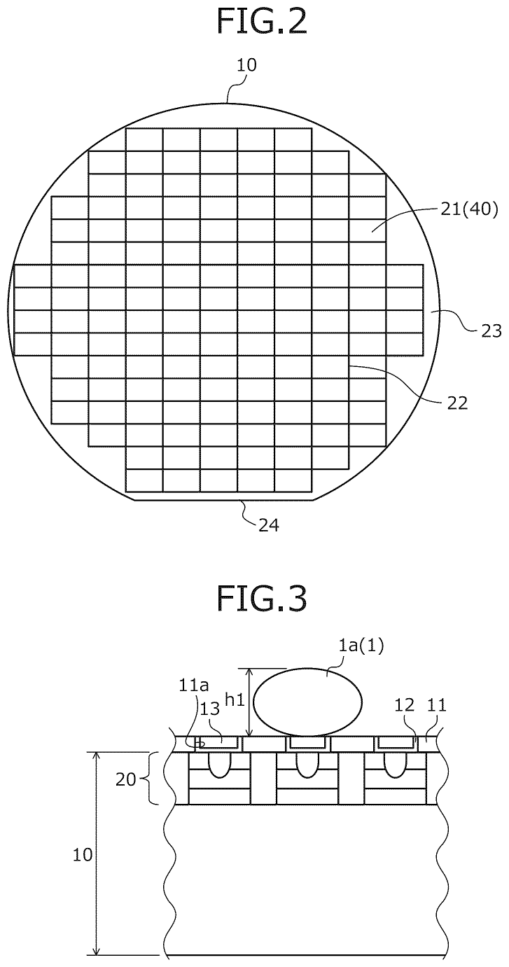

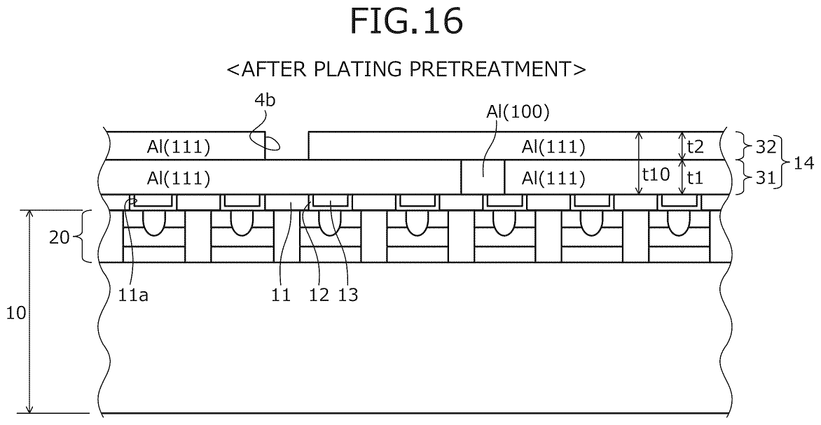

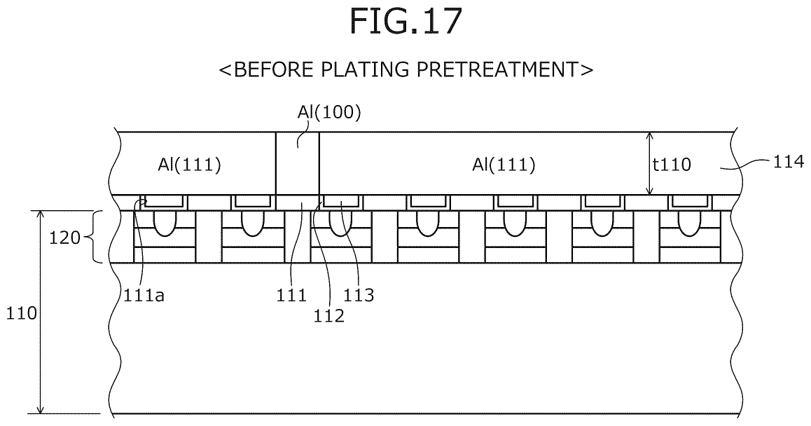

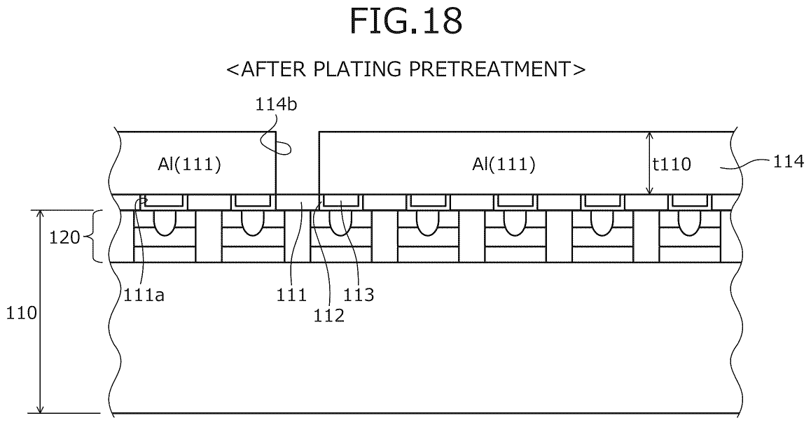

The method of manufacturing the semiconductor device according to the embodiment that solves the problems above is described. FIG. 1 is a flowchart depicting an outline of the method of manufacturing the semiconductor device according to the embodiment. FIG. 2 is a plan view depicting a state when a semiconductor wafer is viewed from a front surface thereof. FIGS. 3, 4, 5, 6A, 6B, 6C, 7A, 7B, 8A, 8B, 15, and 16 are cross-sectional views depicting states of the semiconductor device according to the embodiment during manufacture. FIGS. 9, 10, 11, 12, 13, and 14 are cross-sectional views depicting other states of the semiconductor device according to the embodiment during manufacture. In a semiconductor wafer 10, a portion where foreign matter 1a of a relatively large size is adhered is depicted in FIGS. 3 to 8B while a portion where foreign matter 1b of a relatively small size is adhered is depicted in FIGS. 9 to 14. FIGS. 17 and 18 are cross-sectional views schematically depicting states of the semiconductor device of the reference example during manufacture.

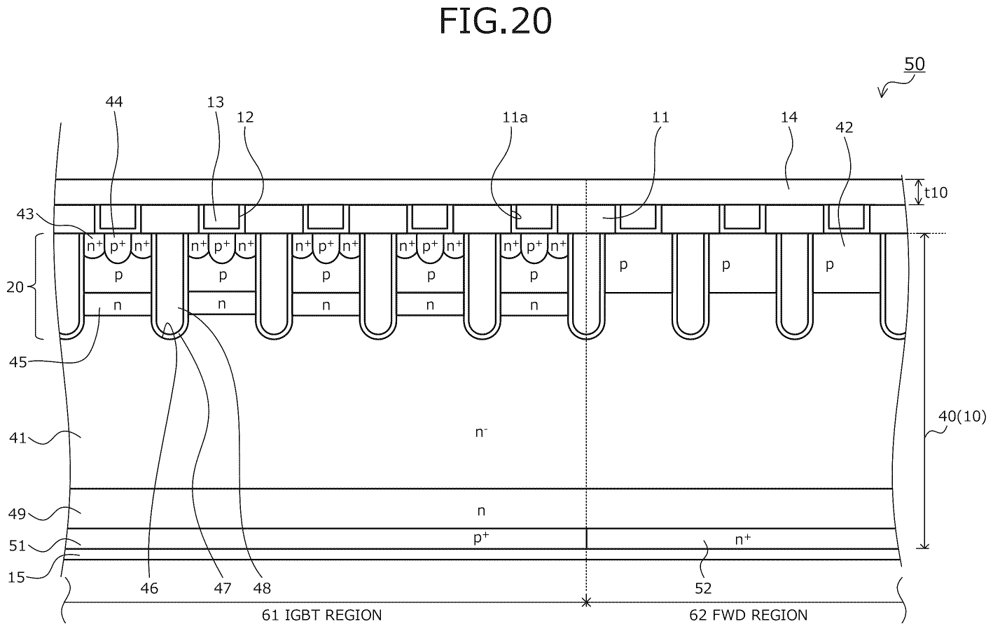

First, as depicted in FIGS. 2, 3, and 9, in the semiconductor wafer 10, at a front surface thereof, a predetermined device structure 20 is formed in each of multiple chip regions 21 (step S1). Next, an interlayer insulating film 11 is formed in an entire area of the front surface of the semiconductor wafer 10 and contact holes 11a that penetrate through the interlayer insulating film 11 in the depth direction are formed. In the contact holes 11a, contacts (electrical contacts) between the device structure 20 and a later-described surface electrode 14 are formed. While the device structure 20 is described hereinafter (refer to FIG. 20), for example, in an instance in which the device structure 20 is a structure with a narrow cell pitch to reduce the size and on-resistance, a width of each of the contact holes 11a is narrow and thus, later-described contact plugs 13 enhance embeddability into the contact holes 11a.

The size of the semiconductor wafer 10 may be suitably set. A material of the semiconductor wafer 10 is, for example, silicon (Si) or silicon carbide (SiC). The chip regions 21 are regions cut from the semiconductor wafer 10, along dicing lines 22, into individual semiconductor chips 40. For example, the chip regions 21 are disposed in a matrix-like pattern in substantially a center of the semiconductor wafer 10 and the dicing lines 22 extend in a grid-like pattern bordering peripheries of all the chip regions 21. A non-operating region 23 that is not used as the semiconductor chips 40 is between an end (wafer end) of the semiconductor wafer 10 and the dicing lines 22 that are closest to the end of the semiconductor wafer 10. The semiconductor wafer 10 may have a notch (not depicted) or an orientation flat 24 indicating surface orientation.

Next, a barrier metal 12 is formed along the surface of the interlayer insulating film 11 and inner walls of the contact holes 11a by a sputtering method. The barrier metal 12 is formed by, for example, a titanium (Ti) film and a titanium nitride (TiN) film stacked in the order state. Next, by a chemical vapor deposition (CVD) method, a conductive film such as, for example, a tungsten (W) film is deposited (formed) on the barrier metal 12 so as to be embedded in the contact holes 11a. Next, an unnecessary portion (portion on the interlayer insulating film 11) of the conductive film is removed by etching, thereby leaving only portions of the conductive film in the contact holes 11a as the contact plugs 13 (step S2).

Foreign matter 1 (1a, 1b) originating from manufacturing processes such as the process at step S2 is adhered to the front surface of the semiconductor wafer 10 (surfaces of the interlayer insulating film 11 and the contact plugs 13) (refer to FIGS. 3 and 9). The foreign matter 1 is assumed to be adhered matter of various substances and shapes such as, for example, carbon (C)-based organic matter, oxides, silicon (Si) pieces that have peeled off from the semiconductor wafer 10, and metals (for example, Ti, W) constituting the barrier metal 12 and the contact plugs 13. For example, the barrier metal 12 deposited by sputtering tends to peel and become the foreign matter 1a of a relatively large size. Heat applied to the surface electrode 14 during manufacture of the semiconductor device is relatively low temperature and thus, even when the foreign matter 1 buried inside the surface electrode 14 is organic matter, the foreign matter 1 is not eliminated (for example, vaporized, etc.) and remains in the product (semiconductor device).

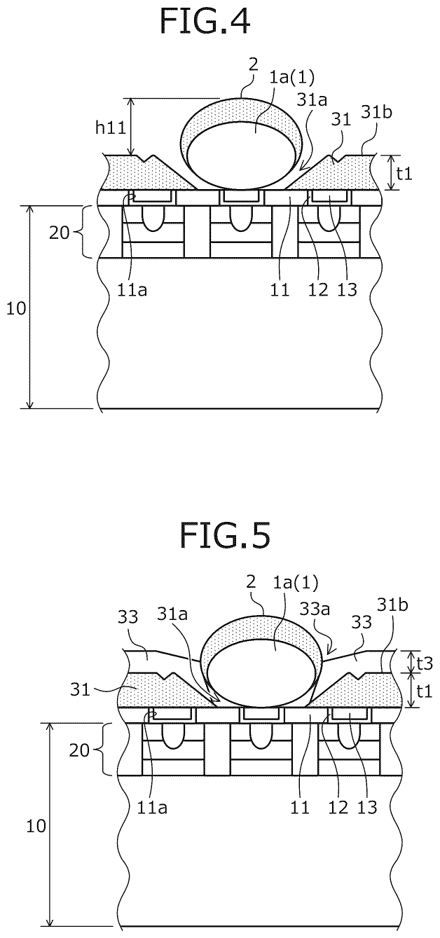

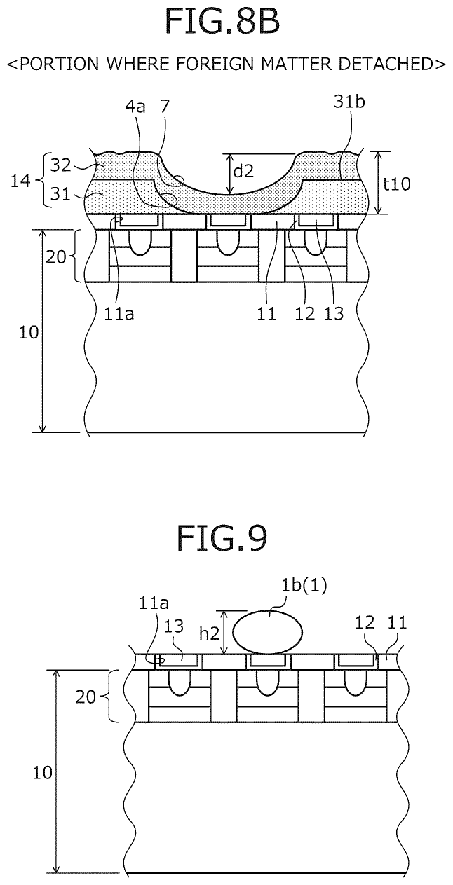

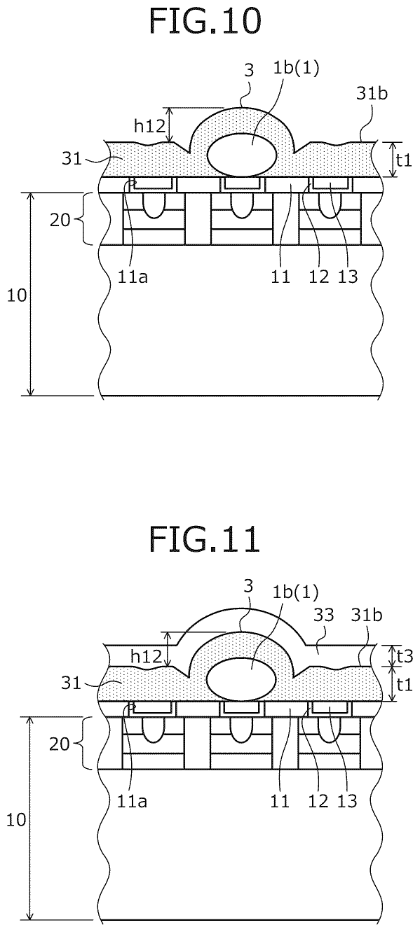

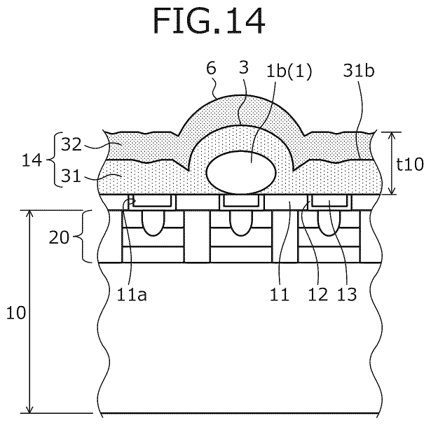

Next, as depicted in FIGS. 4 and 10, a first electrode film 31 constituting a lower portion (first layer) of the surface electrode 14 is deposited (formed) at the front surface of the semiconductor wafer 10 by a sputtering method (step S3: first process). The first electrode film 31 covers an entire area of the surface of the interlayer insulating film 11 and the surfaces of the contact plugs 13. The first electrode film 31 is, for example, an aluminum (Al) film or an Al alloy film containing Al as a main component (for example, 99%) and Si or copper (Cu) or both. A thickness t1 of the first electrode film 31 is thinner than a product thickness t10 of the surface electrode 14 (refer to FIGS. 8A, 8B, and 14) and thus, a convex defect 2 (convex surface defect) caused by the foreign matter 1a of a relatively large size may be reliably generated at the surface of the first electrode film 31 (FIG. 4).

The convex defect 2 of the surface of the first electrode film 31 is a relatively tall convex portion (for example, about 4 μm or more in height) among convex portions of the surface of the first electrode film 31, occurring at portions where the first electrode film 31 covers the foreign matter 1 and is raised. The foreign matter 1a of a relatively large size is attached matter that protrudes from the front surface of the semiconductor wafer 10 to a height h1 (for example, 4 μm or more) and forms a convex portion, causing the convex defect 2 at the surface of the first electrode film 31. A convex portion (base convex portion, not depicted) occurring at the front surface of the semiconductor wafer 10 due to a factor other than the foreign matter 1 also causes a convex portion at the surface of the first electrode film 31. Thus, a convex portion that occurs at the surface of the first electrode film 31 where the first electrode film 31 covers a relatively tall base convex portion (for example, about 4 μm or more in height) also forms the convex defect 2.

In particular, a convex portion of a height h11 of about 4 μm occurring at the surface of the first electrode film 31 due to a convex portion caused by a base convex portion and the foreign matter 1 of the front surface of the semiconductor wafer 10 constitutes the convex defect 2. The height h11 of the convex defect 2 of the surface of the first electrode film 31 is at least equal to a height h1 of a convex portion caused by a base convex portion or the foreign matter 1 of the front surface of the semiconductor wafer 10. The height h11 of the convex defect 2 of the surface of the first electrode film 31 is a height from a surface of a normal portion 31b of the first electrode film 31 to a top of the convex defect 2. The normal portion 31b of the first electrode film 31 is a substantially flat portion free of a convex portion (the convex defect 2, a convex portion 3) and a concave defect (for example, a concave surface defect due to variation of a thickness t1 when the first electrode film 31 is deposited) at the surface of the first electrode film 31.

Further, the height h11 of the convex defect 2 of the surface of the first electrode film 31 is lower than the height h111 of the convex defect 102 that occurs at the surface of the surface electrode 114, which has been increased in thickness to the product thickness t110 by a single process like in the reference example described above (refer to FIG. 25). Poor coverage in a vicinity of the convex defect 2 of the first electrode film 31 may cause a slit (gap) 31a to form in the first electrode film 31 around the convex defect 2. The thickness t1 of the first electrode film 31 is, for example, in a range of about 10% to 90% of the product thickness t10 of the surface electrode 14. Preferably, with consideration of deposition control of the surface electrode 14, the thickness t1 of the first electrode film 31 may be in a range of 25% to 75% of the product thickness t10 of the surface electrode 14. Yet more preferably, the thickness t1 of the first electrode film 31 may be about 50% of the product thickness t10 of the surface electrode 14. Due to deposition (deposition of the surface electrode 14 (first deposition)) of the first electrode film 31, an apparent height h3 of the foreign matter 1a is reduced by the thickness t1 of the first electrode film 31.

The apparent height h3 of the foreign matter 1a is reduced, whereby it becomes easy to achieve both preventing interruption of (breaks in) a resist film 34 used as a mask in the patterning of the surface electrode 14 at later-described step S8 to thereby inhibit generation of a concave defect in a resist defect portion of the resist film 34, and during a plating pretreatment (etching to clean the surface of the surface electrode 14) at later-described step S12, preventing opening of the slit 31a, which is blocked by a second electrode film 32 during deposition (deposition of the surface electrode 14 (second deposition)) of the second electrode film 32 at later-described step S7. In other words, the thickness t1 of the first electrode film 31 is set so that the apparent height h3 of the foreign matter 1a can be reduced and so that a thickness (a thickness t2 of the second electrode film 32) in the second deposition of the surface electrode 14 can be left to be thicker than an etching amount (thickness) of the surface electrode 14 during the plating pretreatment at step S12.

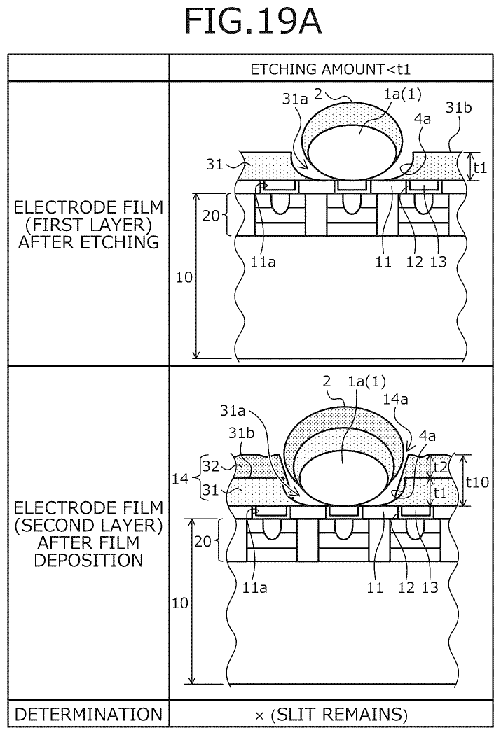

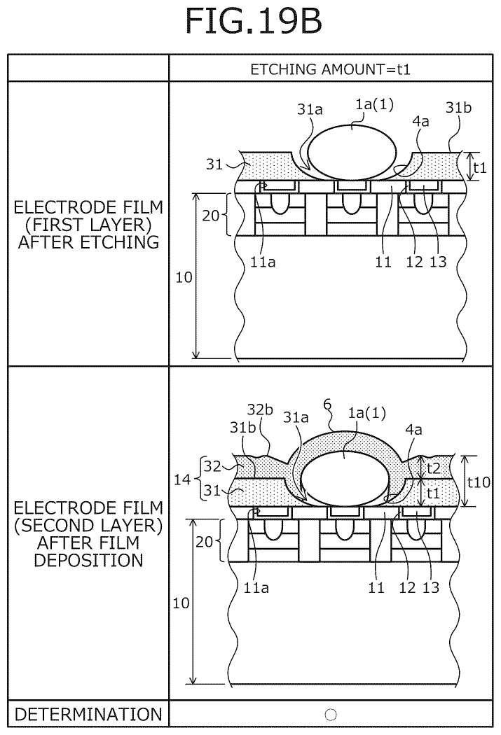

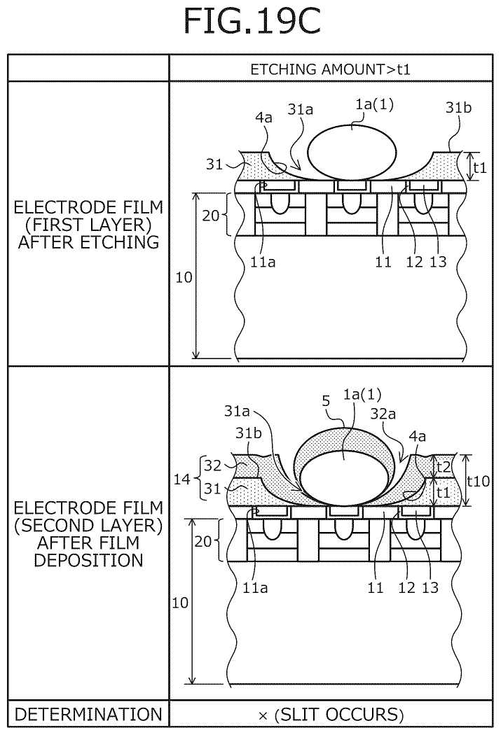

The foreign matter 1b of a relatively small size is entrapped and buried inside the first electrode film 31 during the process at step S3 and does not cause the convex defect 2 (refer to FIGS. 19A, 19B, 19C) to occur. The first electrode film 31, at a portion that covers the foreign matter 1b of a relatively small size, has a substantially flat surface closer to the surface of the normal portion 31b (not depicted) or has the convex portion 3, which is raised and has a height h12 that does not generate the convex defect 2, at the surface (FIG. 10). In other words, the foreign matter 1b of a relatively small size is adhered matter having, from the front surface of the semiconductor wafer 10, a height h2 that does not cause the convex defect 2 to occur at the surface of the first electrode film 31 even when the adhered matter is entrapped in the first electrode film 31. A base convex portion (not depicted) having a relatively low height and occurring at the surface of the first electrode film 31, which is the lower layer, also does not cause the convex defect 2 to occur.

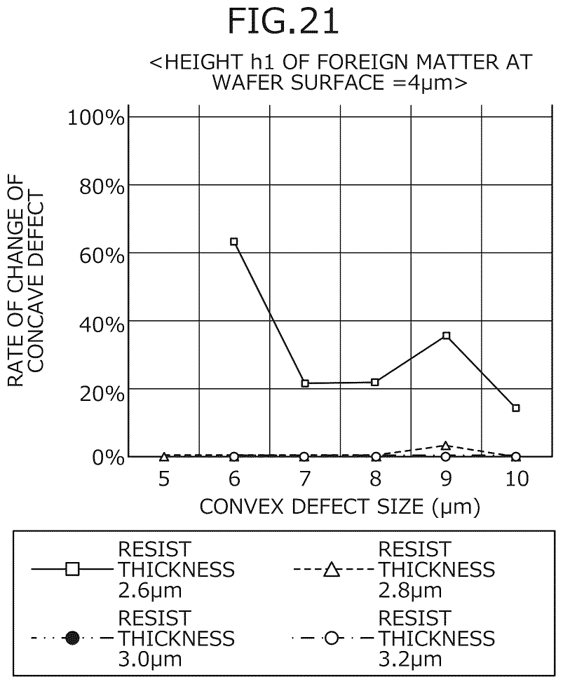

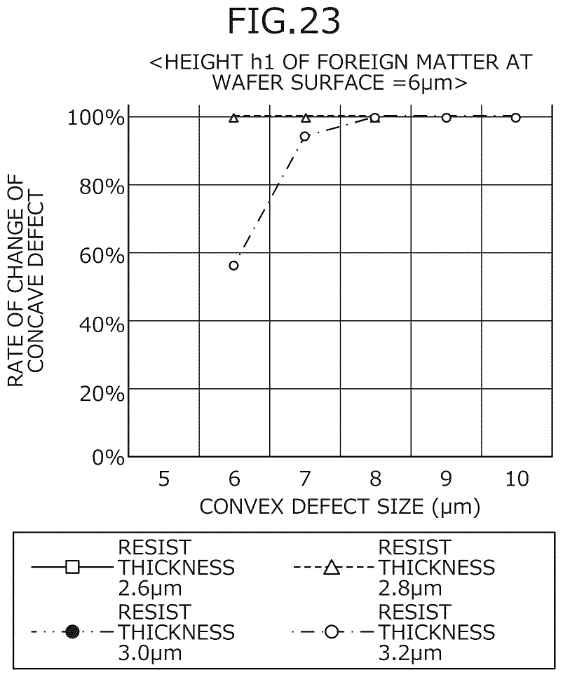

Next, as depicted in FIGS. 5 and 11, an entire area of the surface of the first electrode film 31 is covered by a resist film 33 (step S4: second process). A thickness t3 of the resist film 33 is reduced to an extent that the resist film 33 is interrupted (disconnected) at a portion corresponding to the convex defect 2 of the surface of the first electrode film 31 to thereby generate a resist defect portion 33a and expose the convex defect 2 in the resist defect portion 33a (FIG. 5). Exposure of the convex defect 2 is a state in which at least the top or side surfaces of the convex defect 2 are not covered by the resist film 33. The thickness t3 of the resist film 33 is obtained in advance according to the size of the foreign matter 1 appearing before the process at step S3 and is suitably set so that resist defect portions 33a are generated at all portions of the surface of the first electrode film 31 corresponding to convex defects 2 (refer to FIGS. 21 to 23).

Further, the thickness t3 of the resist film 33 is made thick enough to function as an etching mask to protect the parts of the first electrode film 31 other than the convex defect 2 during the process (etching) at later-described step S5. In particular, when the thickness t3 of the resist film 33 is, for example, about 3.2 um or less, the resist defect portion 33a, which exposes the convex defect 2 may be caused to occur. The thickness t3 of the resist film 33 may be less than a thickness t4 of the resist film 34 and preferably, may be, for example, in a range of about 2.6 μm to 3.0 μm. The thinner is the thickness t3 of the resist film 33, the higher a rate at which the convex defect 2 of the surface of the first electrode film 31 changes to a concave defect 4a during the process at later-described step S5 may be set (hereinafter, concave defect change rate).

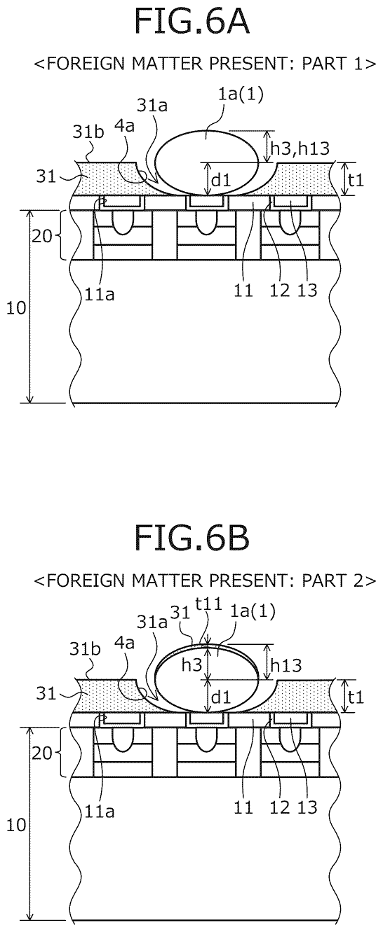

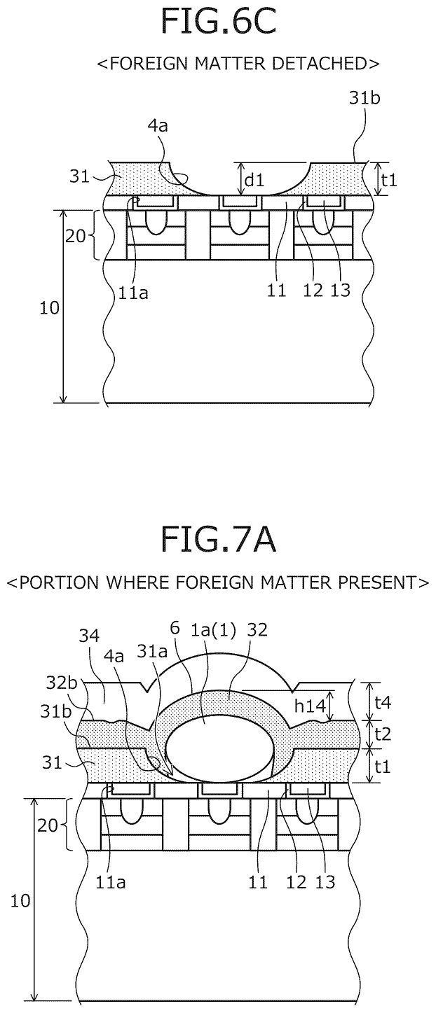

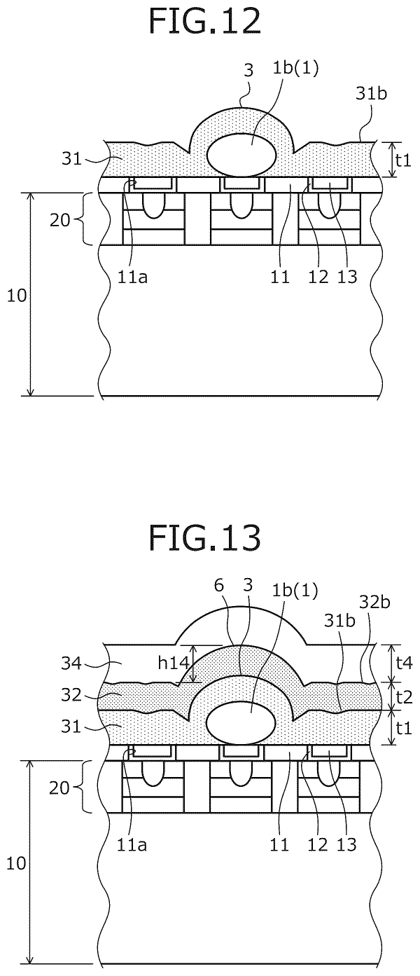

Next, as depicted in FIGS. 6A, 6B, 6C, and 12, the first electrode film 31 exposed in the resist defect portion 33a is etched using the resist film 33 as a mask (step S5: third process). At this time, in the resist defect portion 33a, the convex defect 2 is nearly completely removed, forming the concave defect 4a of a depth d1 and penetrating through the first electrode film 31 in the depth direction. The slit 31a around the convex defect 2 forms, for example, an inner wall of the concave defect 4a. The convex defect 2 may be converted into a convex portion of the height h13 that is low enough such that a convex defect 5 (refer to FIGS. 19A, 19B, 19C) does not occur at the surface of the second electrode film 32 during the process at later-described step S7. In other words, a height position of the surface of portions of the first electrode film 31 exposed at the resist defect portions 33a may be lowered by the process at step S5.

After the process at step S5, the foreign matter 1a may be left in the concave defect 4a (FIGS. 6A and 6B), or the first electrode film 31 may be left having an ultra-thin thickness t11 on the foreign matter 1a (FIG. 6B), or during the process at step S5, the foreign matter 1a may be detached from the semiconductor wafer 10 and not remain in the concave defect 4a (FIG. 6C). Process conditions (etching conditions for the first electrode film 31) at step S5 may be obtained in advance according to material composition, the thickness t1 of the first electrode film 31, etc. In particular, the process at step S5 suffices to be performed under etching conditions that enable etching of the first electrode film 31 in the depth direction by an amount corresponding to the thickness t1 of the first electrode film 31. A reason for this is that even when the etching amount of the first electrode film 31 is greater than the thickness t1 of the first electrode film 31, or when the etching amount of the first electrode film 31 is insufficient and is less than the thickness t1 of the first electrode film 31, it is estimated that the coverage and embeddability of the second electrode film 32 will deteriorate in the process at later-described step S7.

The etching amount of the first electrode film 31 in the process at step S5 is described with reference to FIGS. 19A, 19B, and 19C. FIGS. 19A, 19B, 19C are tables of cross-sectional views schematically depicting states of surface electrodes of an example and the reference example during formation. In FIGS. 19A, 19B, and 19C, an upper portion depicts a state after the process (etching of the first electrode film 31 (electrode film of the first layer)) at step S5 while a lower portion depicts a state after the process (deposition of the second electrode film 32 (electrode film of the second layer)) at step S7. FIGS. 19A, 19B, 19C show the etching amounts of the first electrode film 31 and the respective etching amounts are for instances in which the etching amount is less than the thickness t1 of the first electrode film 31 (comparison example), the etching amount is the same as the thickness t1 of the first electrode film 31 (example), and the etching amount is more than the thickness t1 of the first electrode film 31 (comparison example). In FIGS. 19A, 19B, and 19C, “O” indicates a determination of conforming and “X” indicates a determination of non-conforming. In other words, the chip regions 21 (refer to FIG. 2) in states for which the determination in FIGS. 19A, 19B, and 19C are “x” are non-conforming.

The etching amount of the first electrode film 31 in the process at step S5 is set to be about the thickness t1 of the first electrode film 31 (upper portion of FIG. 19B), whereby the convex defect 2 (portion of the first electrode film 31 on the foreign matter 1a) is nearly completely removed and the progress of the etching in a horizontal direction (direction parallel to the front surface of the semiconductor wafer 10) of the first electrode film 31 at the resist defect portion 33a may be controlled. The concave defect 4a of a same width as the width of the resist defect portion 33a is formed. The slit 31a around the convex defect 2 becomes the inner wall of the concave defect 4a with nearly no change in position a horizontal direction. For example, the concave defect 4a is formed so that one or more slits 31a become connected, whereby the slits 31a disappear. Even when the foreign matter 1a remains in the concave defect 4a, the portion of the first electrode film 31 on the foreign matter 1a is completely removed (or has the ultra-thin thickness t11), whereby a gap between the foreign matter 1a and the inner wall of the concave defect 4a widens on the opening side and the embeddability of the second electrode film 32 into the concave defect 4a is enhanced (lower portion of FIG. 19B).

On the other hand, when the etching amount of the first electrode film 31 in the process at step S5 is insufficient, the convex defect 2 cannot be removed sufficiently (upper portion of FIG. 19A). When the foreign matter 1a remains in the concave defect 4a, the convex defect 2 and the slit 31a are transferred to the second electrode film 32 due to a shadowing effect during sputtering of the second electrode film 32 (lower portion of FIG. 19A). When the etching amount of the first electrode film 31 is excessive in the process at step S5, the convex defect 2 (portion of the first electrode film 31 on the foreign matter 1a) is completely removed, however, the first electrode film 31 is etched in a horizontal direction, whereby the width of the concave defect 4a increases (upper portion of FIG. 19C). When the gap between the foreign matter 1a and the inner wall of the concave defect 4a becomes too wide, the second electrode film 32 having a same thickness as the product thickness t10 of the surface electrode 14 is embedded in the concave defect 4a. Thus, similar to the reference example (refer to FIG. 25), the convex defect 5 caused by the foreign matter 1a occurs at the surface of the second electrode film 32 and a slit 32a that penetrates through the second electrode film 32 around the convex defect 5 may further occur (lower portion of FIG. 19C).

In other words, the etching amount of the first electrode film 31 in the process at step S5 is set to be about the thickness t1 of the first electrode film 31, whereby neither the convex defect 5 nor the slit 32a occur in the surface electrode 14. Preferably, the process at step S5 may be performed by wet etching. A reason for this is that the first electrode film 31 is etched having a substantially uniform thickness and thus, even when the first electrode film 31 remains on the foreign matter 1a, the first electrode film 31 is left with the thickness t11 being substantially uniform along the surface of the foreign matter 1a. When the process at step S5 is performed by dry etching, the first electrode film 31 remains on the top of the foreign matter 1a so as to protrude upward with a substantially rectangular shape in a cross-sectional view (not depicted) and there is a risk that the convex defect 2 will not disappear. A temperature during the process at step S5 is relatively low in a range of, for example, about 60 degrees C. to 70 degrees C. Thus, even when the foreign matter 1a left in the concave defect 4a and the foreign matter 1b entrapped in the first electrode film 31 is organic matter, the foreign matter 1a, 1b does not disappear and remain buried in the surface electrode 14 of the product. Thereafter, the resist film 33 is removed (ashing) (step S6: fourth process).

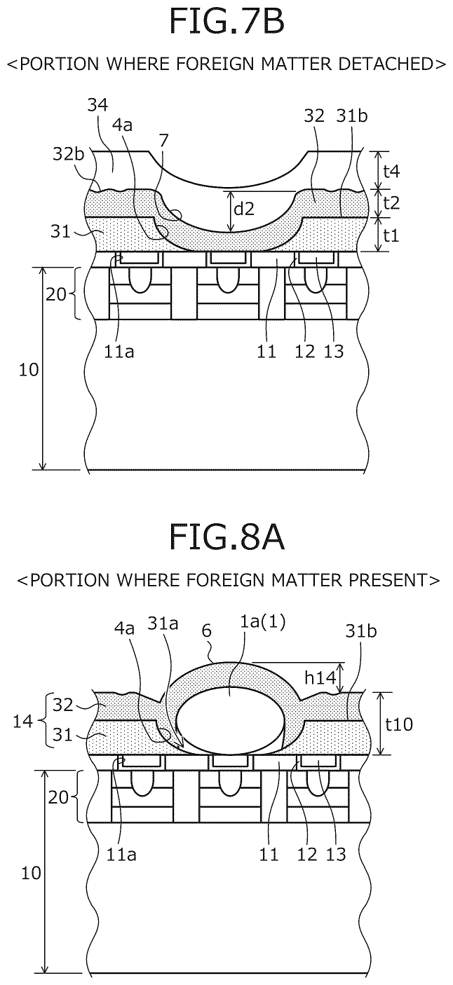

Next, as depicted in FIGS. 7A, 7B, and 13, the second electrode film 32 constituting an upper portion (second layer) of the surface electrode 14 is deposited (formed) in an entire area of the surface of the first electrode film 31 by a sputtering method (step S7: fifth process). The thickness t2 of the second electrode film 32 is set to be a thickness obtained by subtracting the thickness t1 of the first electrode film 31 from the product thickness t10 of the surface electrode 14. A material and deposition conditions of the second electrode film 32 are the same as those for the first electrode film 31. The surface of the second electrode film 32 is concave to the depth d1 (=the thickness t1 of the first electrode film 31) of the concave defect 4a and a concave portion 7 having a depth d2 not penetrating through the surface electrode 14 occurs at the surface of the surface electrode 14. Even when the foreign matter 1a of a relatively large size remains in the concave defect 4a, a gap between the foreign matter 1a and the inner wall of the concave defect 4a may be embedded with the second electrode film 32.

Further, even when the foreign matter 1a of a relatively large size remains in the concave defect 4a, as described above, the apparent height h3 of the foreign matter 1a is reduced by an amount equivalent to the thickness t1 of the first electrode film 31 (refer to FIGS. 6A, 6B, and 6C). The apparent height h3 of the foreign matter 1a is the height h13 from the surface of the normal portion 31b of the first electrode film 31 to the top of the foreign matter 1a. In other words, the foreign matter 1a becomes a convex portion with the height h13, which is lower than the height h11 of the convex defect 2. Further, even when a convex portion 6 occurs at the surface of the second electrode film 32 due to the foreign matter 1a, the height h14 (refer to FIGS. 7A, 7B, and 13) of the convex portion 6 is about the thickness t2 of the second electrode film 32 and lower than the height h111 of the convex defect 102 occurring at the surface of the surface electrode 114 of the reference example (refer to FIG. 25). Thus, neither the slit 32a nor the convex defect 5 caused by the foreign matter 1a occurs in the second electrode film 32 (refer to FIGS. 19A, 19B, and 19C).

The foreign matter 1a of a relatively large size entrapped in the second electrode film 32 and the foreign matter 1b of a relatively small size entrapped in the first electrode film 31 during the process at step S3 remain in the product (semiconductor device), buried in the first and second electrode films 31, 32 (the surface electrode 14). Regardless of the size of the foreign matter 1 (1a, 1b), the second electrode film 32, at a portion thereof covering the foreign matter 1 has a substantially flat surface in a vicinity of the surface of a normal portion 32b (not depicted) or has the convex portion 6 that is raised by the height h14, which is not high enough to become the convex defect 5 (refer to FIGS. 19A, 19B, 19C) (refer to FIGS. 8A, 8B, and 14). The height h14 of the convex portion 6 of the surface of the second electrode film 32 is a height from the surface of the normal portion 32b of the second electrode film 32 to the top of the convex portion 6.

Next, the first and second electrode films 31, 32 are patterned by photolithography and etching and portions constituting the surface electrode 14 are left (step S8: sixth process). At step S8, the resist film (resist mask) 34, which covers respective active regions of the chip regions 21, is formed on the second electrode film 32 (FIGS. 7A, 7B, and 13). The thickness t4 of the resist film 34 is, for example, about 3.2 μm. In openings (not depicted) of the resist film 34, edge termination regions (not depicted) and the dicing lines 22 (refer to FIG. 2) are exposed. Further, as depicted in FIGS. 8A, 8B, and 14, etching is performed using the resist film 34 as a mask, whereby in each of the active regions of the chip regions 21, portions of the first and second electrode films 31, 32 constituting the surface electrode 14 are left. The process at step S8 is, for example, performed by wet etching. Subsequently, the resist film 34 is removed.

As described, the convex defect 5 does not occur at the surface of the second electrode film 32 and thus, breaks in the resist film 34 caused by unevenness (the concave portion 7 caused by the concave defect 4a, the convex portion 6 caused by the foreign matter 1a and having the height h14 that is relatively low) of the surface of the surface electrode 14 do not occur during the process at step S8. As a result, the occurrence of concave defects (metal defects, not depicted) resulting from the surface electrode 14 being partially etched during the process at step S8 may be reduced. The product thickness t10 of the surface electrode 14 is a sum of the thicknesses of the first and second electrode films 31, 32 and in particular, is in a range of about 4 μm to 6 μm and may be, for example, about 5 μm. A temperature during the process at step S8 is, for example, in a relatively low range of about 155 degrees C. to 165 degrees C. and thus, even when the foreign matter 1 entrapped in the surface electrode 14 (first and second electrode films 31, 32) is organic matter, the foreign matter 1 remains in the surface electrode 14 of the product without disappearing.

Next, visual inspection of the semiconductor wafer 10 is performed using general visual inspection equipment (not depicted) (step S9). As described, the convex defect 5 does not occur at the surface (surface of the second electrode film 32) of the surface electrode 14 and thus, in the inspection at step S9, only concave defects of the surface electrode 14 may be detected for by the visual inspection equipment. For example, among the concave portions (not depicted) formed by the surface electrode 14 being partially etched at the concave portion 7 caused by the concave defect 4a and occurring at the surface of the surface electrode 14 and a resist defect portion (for example, a defective portion caused by variation in thickness) of the resist film 34 during the process at step S8, concave portions having a concave shape that causes product defects are detected as concave defects. For example, a concave portion occurring in a resist defect portion of the resist film 34 penetrates through the surface electrode 14 in the depth direction, whereby plating solution penetrates into a lower layer from the concave portion and causes a product defect to occur.

Next, an anneal treatment (heat treatment) for sintering the surface electrode 14 is performed. An anneal temperature for the sintering of the surface electrode 14 is, for example, in a range of about 378 degrees C. to 382 degrees C. During the anneal treatment, an ohmic contact between the barrier metal 12 and the semiconductor wafer 10 may be formed. Next, a surface protective film (passivation film, not depicted) containing, for example, a polyimide is formed at the front surface of the semiconductor wafer 10 (surface of the surface electrode 14) (step S10). Next, openings are formed in the surface protective film by photolithography and etching and in each of the openings of the surface protective film, the surface electrode 14 of each of the chip regions 21 is exposed. The portions of the surface electrodes 14 exposed in the openings of the surface protective film constitute electrode pads. Next, by a general method, parts of the back side of the semiconductor wafer 10 are formed (step S11).

In the process at step S11, for example, the semiconductor wafer 10 is ground from the back surface to have a product thickness used for a semiconductor device 50 (refer to FIG. 20). After the grinding, in the semiconductor wafer 10, at the back surface thereof, predetermined diffused regions (in FIG. 20, an n⁺-type FS layer 49, a p⁺-type contact region 51, and an n⁺-type cathode region 52) are formed by ion implantation and a dopant activating treatment by laser annealing from the back surface of the semiconductor wafer 10. From the front surface or the back surface of the semiconductor wafer 10, for example, helium (He) may be irradiated to thereby induce lifetime killers in a predetermined region in the semiconductor wafer 10. Next, by a sputtering method, a surface electrode (in FIG. 20, back electrode 15) is formed at the back surface of the semiconductor wafer 10.

Next, a plating film (not depicted) such as a nickel (Ni) film for solder bonding is formed at the surface of the surface electrode 14 by a plating treatment (step S12). During the process at step S12, penetration of the plating solution into a lower layer (the interlayer insulating film 11 and the contact plugs 13) of the surface electrode 14 may be prevented. A reason for this is that, as described, the slit 32a (refer to FIGS. 19A, 19B, 19C) caused by the convex defect 5 does not occur in the surface electrode 14, i.e., the surface electrode 14 is free of the slit 32a. In addition, the surface electrode 14 has a two-layer structure constituted by the first and second electrode films 31, 32, which are deposited at different timings, and thus, even when a concave portion 4b occurs in the surface electrode 14 due to etching during the plating pretreatment at step S12, the concave portion 4b does not penetrate through the surface electrode 14 in the depth direction.

The Al film or Al alloy film deposited by a sputtering method tends to be oriented in the (111) plane, which is the closest packed plane of atoms in face-centered cubic (fcc) crystals (crystal grains grow in a crystal orientation perpendicular to the (111) plane, and the (111) plane is exposed at the Al surface: hereafter referred to as (111) orientation), and contains a small amount of crystal grains with {001} and {101} orientations. The inventors confirmed this orientation of Al by using electron backscatter diffraction pattern (EBSD) analysis. While dependent on the composition of the etching solution, the inventors have further confirmed that the (100) surface of Al is easily etched.

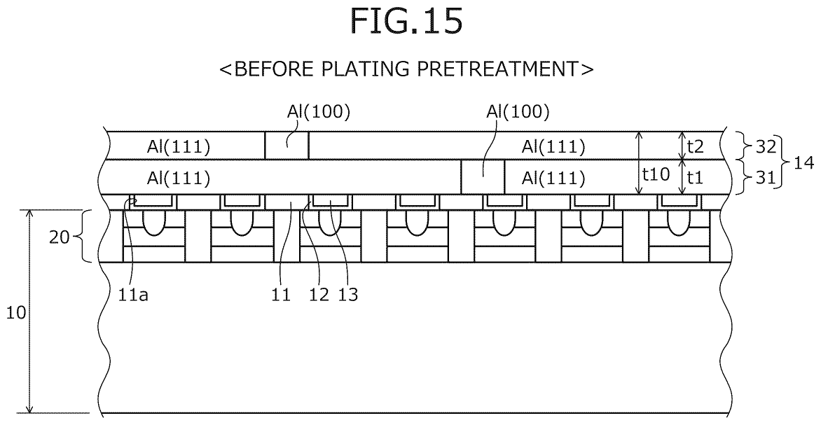

Similar to the reference example, when the thickness of the surface electrode 114 is increased to the product thickness t110 by a single sputtering session, crystal grains for the product thickness t110 of the surface electrode 114 grow in the same crystal orientation, and crystal grain boundaries between (111) plane-oriented Al crystal grains and crystal grains oriented in other crystal planes of Al penetrate through the surface electrode 114 in the thickness direction (FIG. 17). In FIG. 17, portions where (100) plane-oriented Al crystal grains grow are indicated by Al(100) and portions where (111) plane-oriented Al crystal grains grow are indicated by Al(111) (similarly in FIGS. 15, 16, and 18). Thus, during the plating pretreatment, the surface electrode 114 is locally etched at the Al (100) surface and a concave defect 114b that penetrates through the surface electrode 114 in the depth direction is generated (FIG. 18).

In contrast, in the present embodiment, the first and second electrode films 31, 32 constituting the surface electrode 14 are deposited at mutually different timings. Thus, positions where the (100) plane-oriented Al crystal grains grow differ in the first and second electrode films 31, 32 (FIG. 15), and it is assumed that the (100) plane-oriented Al crystal grains in the first electrode film 31 and the (100) plane-oriented Al crystal grains in the second electrode film 32 are unlikely to face each other in the thickness direction of the surface electrode 14. Thus, it is assumed that, during the plating pretreatment, even when the second electrode film 32 is locally etched at the Al (100) surface and the concave portion 4b occurs, the concave portion 4b only penetrates through the second electrode film 32 in the depth direction and terminates at the interface between the first and second electrode films 31, 32.

Next, various inspections of the semiconductor wafer 10 are performed (step S13), ending the wafer process. The inspections at step S13 may be, for example, electrical characteristic tests that inspect basic functions and characteristics through input and output of electrical signals and thereby screen (select) the chip regions 21 that deviate from standards and are non-conforming; the inspections may be performed on all the chip regions 21 on the semiconductor wafer 10, or may be performed only on the chip regions 21 that are not determined to be non-conforming by the inspection at step S9 above. Thereafter, the semiconductor wafer 10 is cut (diced) along the dicing lines 22 thereby separating the chip regions 21 into the individual semiconductor chips 40 (refer to FIG. 20) and completing the product (the semiconductor device 50).

An example of the structure of a semiconductor device manufactured according to the method of manufacturing the semiconductor device according to the embodiments above is described with reference to FIG. 20. FIG. 20 is a cross-sectional view depicting an example of the structure of the semiconductor device manufactured according to the method of manufacturing the semiconductor device according to the embodiments. In FIG. 20, the active region is depicted while the edge termination region is not depicted. The semiconductor device 50 depicted in FIG. 20 is a reverse conducting insulated gate bipolar transistor (RC-IGBT) in which a trench gate type IGBT and a diode connected in antiparallel to the IGBT are integrated on a single chip, the semiconductor chip (semiconductor substrate) 40.

The semiconductor chip 40 is one of the chip regions 21 cut from the semiconductor wafer 10 after the process at step S13 above (after completion of the wafer process) (refer to FIGS. 1 and 2). In an instance in which the semiconductor device 50 has a breakdown voltage class of 1200V, the thickness of the semiconductor chip 40 is, for example, about 725 μm. When the material of the semiconductor chip 40 is, for example, Si, the front surface of the semiconductor chip 40 is, for example, a (001) plane. In the semiconductor chip 40, in the active region, an IGBT region 61 constituting an operating region of the IGBT and a FWD region 62 constituting an operating region of a freewheeling diode (FWD) are provided adjacent to each other in a direction parallel to the front surface of the semiconductor chip 40.

The active region is a region through which a main current flows when the semiconductor device 50 is on. The edge termination region is a region between the active region and a side surface of the semiconductor chip 40 and surrounds a periphery of the active region. In the edge termination region, a predetermined voltage withstanding structure is provided. In the active region, at the front surface of the semiconductor chip 40, the device structure 20, the barrier metal 12, the contact plugs 13, and the surface electrode 14 described above are provided. In an entire area of the front surface of the semiconductor chip 40, the interlayer insulating film 11 containing, for example, a borophosphosilicate glass (BPSG) is provided. In the edge termination region, between the front surface of the semiconductor chip 40 and the interlayer insulating film 11, for example, a field oxide film formed by thermal oxidation of the front surface of the semiconductor chip 40 is provided.

A portion of the semiconductor chip 40 other than the device structure 20, the later-described n⁺-type FS layer 49, the p⁺-type contact region 51, and the n⁺-type cathode region 52 constitutes an n³¹-type drift region 41. The device structure 20 is constituted by p-type base regions 42, n⁺-type emitter regions 43, p⁺-type contact regions 44, trenches 46, gate insulating films 47, and gate electrodes 48. The p-type base regions 42 are provided in the active region, in an entire area between the front surface of the semiconductor chip 40 and the n⁻-type drift region 41. Each of the p-type base regions 42 has a lower surface (surface facing the p⁺-type contact region 51 and the n⁺-type cathode region 52) that is in contact with the n⁻-type drift region 41. The p-type base regions 42 function as a p-type anode region in the FWD region 62.

The n⁺-type emitter regions 43 and the p⁺-type contact regions 44 are each selectively provided in the IGBT region 61, between the front surface of the semiconductor chip 40 and the p-type base regions 42 and are not provided in the FWD region 62. The n⁺-type emitter regions 43 and the p⁺-type contact regions 44 have lower surfaces that are in contact with the p-type base regions 42 and at the front surface of the semiconductor chip 40, the n⁺-type emitter regions 43 and the p⁺-type contact regions 44 are in contact with the barrier metal 12. The n⁺-type emitter regions 43 are in contact with the gate insulating films 47 at sidewalls of the trenches 46 and face the gate electrodes 48 via the gate insulating films 47. The p⁺-type contact regions 44 may be omitted. When the p⁺-type contact regions 44 are omitted, instead of the p⁺-type contact regions 44, the p-type base regions 42 reach the front surface of the semiconductor chip 40.

In the IGBT region 61, n-type carrier storage (CS) regions 45 may be provided between and in contact with the n′-type drift region 41 and the p-type base regions 42. The n-type carrier storage regions 45 serve as a barrier of minority carriers (holes) and have a function of storing minority carriers. The n-type carrier storage regions 45 may be in contact with the gate insulating films 47 at the sidewalls of the trenches 46. The trenches 46 penetrate through the p-type base regions 42 from the front surface of the semiconductor chip 40 and terminate in the n⁻-type drift region 41. The trenches 46 are provided in the IGBT region 61 and the FWD region 62. In the trenches 46, the gate electrodes 48 containing, for example, a polysilicon (poly-Si) are provided via the gate insulating films 47.

In the interlayer insulating film 11, the contact holes 11a, which penetrate through the interlayer insulating film 11 in the depth direction and reach the front surface of the semiconductor chip 40, are provided. The contact holes 11a in the IGBT region 61 expose the n⁺-type emitter regions 43 and the p⁺-type contact regions 44. The contact holes 11a in the FWD region 62 expose the p-type base regions 42. The barrier metal 12 is provided along inner walls (side surfaces of the interlayer insulating film 11 and the front surface of the semiconductor chip 40) of the contact holes 11a. The barrier metal 12 is in ohmic contact with the n⁺-type emitter regions 43 and the p⁺-type contact regions 44 in the contact holes 11a of the IGBT region 61 and is in contact with the p-type base regions 42 in the contact holes 11a of the FWD region 62.

The contact plugs 13 are embedded on the barrier metal 12 in the contact holes 11a. The surface electrode 14 is provided on the interlayer insulating film 11 and the contact plugs 13 and is electrically connected to the p-type base regions 42, the n⁺-type emitter regions 43, and the p⁺-type contact regions 44 via the contact plugs 13 and the barrier metal 12. The surface electrode 14 functions as an emitter electrode in the IGBT region 61 and functions as an anode electrode in the FWD region 62. In the n-type drift region 41 in the FWD region 62, at a position closer to the front surface of the semiconductor chip 40 than is the n⁺-type FS layer 49, a lifetime control region (not depicted) formed by inducing lifetime killers by, for example, helium (He) irradiation may be provided.

The n⁺-type FS layer 49 is provided in an entire area between the back surface of the semiconductor chip 40 and the n-type drift region 41. The p⁺-type contact region 51 is provided in a region between the back surface of the semiconductor chip 40 and the n⁺-type FS layer 49, excluding the FWD region 62. In the FWD region 62, the n⁺-type cathode region 52 is provided between the back surface of the semiconductor chip 40 and the n⁺-type FS layer 49. The n⁺-type cathode region 52 is adjacent to the p⁺-type contact region 51 in a direction parallel to the back surface of the semiconductor chip 40. The back electrode 15 is provided at the back surface of the semiconductor chip 40 and is in contact with the p⁺-type contact region 51 and the n⁺-type cathode region 52. The back electrode 15 functions as a collector electrode in the IGBT region 61 and functions as a cathode electrode in the FWD region 62.

As described, according to the embodiment, the surface electrode of the front surface of the semiconductor substrate has a two-layer structure including the first and second electrode films, which are deposited (formed) at mutually different timings. The first electrode film is deposited having a thickness that is thinner than the product thickness of the surface electrode and the entire surface of the first electrode film is covered with a resist film after convex defects are formed at the surface of the first electrode film due to relatively large foreign matter that has adhered to the front surface of the semiconductor substrate during processes before the deposition of the first electrode film and due to relatively tall convex defects that have occurred at the front surface of the semiconductor substrate. In the resist film, a resist defect portion caused by a convex defect at the surface of the first electrode film is intentionally induced. Further, the convex defect exposed in the resist defect portion is etched and changed into a concave defect or a convex portion having a relatively low height, whereby a height position of the portion of the first electrode film exposed in the resist defect portion may be lowered. Thus, the surface of the second electrode film, which is deposited on the entire surface of the first electrode film is free of convex defects.

Convex portions with a relatively low height and concave defects occurring in the first electrode film, and slits remaining in the first electrode film are completely covered by the second electrode film. Even when foreign matter of a relatively large size remains in a concave defect, the apparent height of the foreign matter is reduced and thus, a shadowing effect during sputtering is suppressed and the foreign matter of a relatively large size is also completely covered by the second electrode film. The surface of the second electrode film (surface of the surface electrode) is free of convex defects and thus, during patterning of the surface electrode, the occurrence of concave defects (metal defects) in the surface electrode may be reduced and the conforming rate of the semiconductor device (product) is enhanced. While a concave portion caused by a concave defect of the first electrode film occurs at the surface of the surface electrode, the concave portion of the surface of the surface electrode is a slight recess having a depth that is about a same as the thickness of the first electrode film and thus, the quality of the semiconductor device is not adversely affected. Further, after patterning of the surface electrode, detection of only concave defects of the surface electrode suffices and thus, accuracy of the visual inspection of the semiconductor wafer may be enhanced.

Further, according to the embodiment, the surface electrode may be formed without changing design conditions (product thickness, materials) or the like and thus, variation of characteristics of the semiconductor device may be prevented. Further, according to the embodiment, existing semiconductor manufacturing equipment may be used and thus, increases in costs such as in facility investment may be suppressed.

Verification of the thickness t3 of the resist film 33 (refer to FIGS. 1 and 5) during the process at step S4 of the method of manufacturing the semiconductor device according to the embodiment is described. FIGS. 21, 22, and 23 are characteristics diagrams showing experimental results for a relationship between resist film thickness and the concave defect change rate of convex defects of the surface of the first electrode film. The processes at steps S3 to S5 were performed on samples in which the height h1 of a convex portion of the front surface of the semiconductor wafer 10 (wafer surface) due to a base convex portion, the foreign matter 1a, etc. was assumed to be 4 μm, 5 μm, and 6 μm, respectively; the thickness (resist thickness) t3 of the resist film 33 in the process at step S4 was variously changed and the process at step S5 was performed; the results thereof are shown in FIGS. 21, 22, and 23. In FIGS. 21 to 23, a horizontal axis is the size of the convex defect 2 that occurs at the surface of the first electrode film 31 and may be the height h11 of the convex defect 2 or the width (not depicted) of the convex defect 2. A vertical axis is the concave defect change rate (rate at which the convex defect 2 is converted into the concave defect 4a, refer to FIGS. 6A, 6B, 6C) during the process at step S5. In general, in instances in which the height of the shape of the foreign matter 1a is greater than the width thereof, the concave defect tends to be formed while in instances in which the height of the shape of the foreign matter 1a is less than the width thereof, concave defect is not easily formed.

As depicted in FIGS. 21, 22, and 23, it was confirmed that the convex defect 2, which occurs at the surface of the first electrode film 31 due to a convex portion at the front surface of the semiconductor wafer 10 and having the height h1, which is 4 μm or greater, could be converted into the concave defect 4a during the process at step S5. In addition, it was confirmed that the thinner the thickness t3 of the resist film 33 was during the process at step S4 or the higher the height h1 of the convex portion of the front surface of the semiconductor wafer 10 was, the higher the concave defect change rate became during the process at step S5. Thus, preferably, the thickness t1 of the first electrode film 31 may be suitably adjusted to cause the convex defect 2 of the height h11, which is relatively high, to occur at the surface of the first electrode film 31. In particular, preferably, the height h11 of all the convex defects 2 of the surface of the first electrode film 31 may be at least the height h1 (i.e., at least 4 μm, preferably, 5 μm or more) of the convex portion of the wafer surface of the samples depicted in FIGS. 21 to 23.

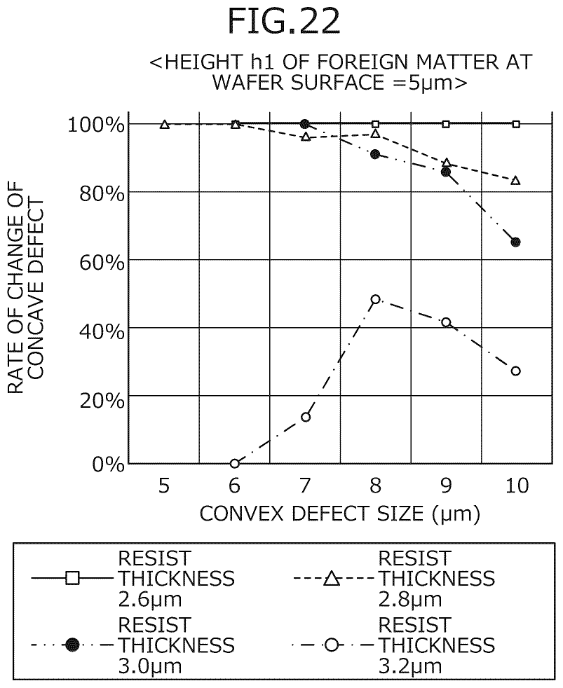

As a result, the thickness t3 of the resist film 33 during the subsequent process at step S4 is suitably adjusted, whereby breakage of the resist film 33 at all the convex defects 2 of the surface of the first electrode film 31 is caused and all the convex defects 2 can be exposed in the resist defect portion 33a. Thus, in the process at step S5, all the convex defects 2 of the surface of the first electrode film 31 may be converted into the concave defect 4a or may be converted into a convex portion with a relatively low height. For example, in the results shown in FIG. 22, it was confirmed that in the sample in which the thickness t3 of the resist film 33 during the process at step S4 was 2.6 μm, a concave defect change rate of 100% during the process at step S5 could be achieved. Here, while the first electrode film 31 was an Al—Si alloy film, it is assumed that the same results may be obtained with an Al alloy film of a different composition containing Al.

In the disclosure above, without limitation to the described embodiments, various modifications within a range not departing from the spirit of the disclosure are possible. For example, in the processes at steps S3 and S7 (in particular, in the process at step S7), the first and second electrode films (lower and upper portions of the surface electrode) may be deposited by a high-temperature reflow sputtering method (method of heating the semiconductor wafer by a high temperature in a range of, for example, about 450 degrees C. to 500 degrees C. and thereby performing sputtering while reflowing the Al-based material). The present disclosure is applicable to various types of semiconductor devices independent of the material of the semiconductor wafer, the wafer size, and the device structure.

The method of manufacturing the semiconductor device according to the present disclosure achieves an effect in that the rate of conforming products may be enhanced.

As described, the method of manufacturing the semiconductor device according to the present disclosure is useful for power semiconductor devices used in power converting equipment, power generating devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device, the method comprising:
forming a first electrode film at a surface of a semiconductor wafer, the first electrode film having a convex defect at a surface thereof;
covering the surface of the first electrode film with a resist film and inducing a break in the resist film at a portion corresponding to the convex defect, thereby generating a resist defect portion from which the convex defect is exposed;
etching the convex defect exposed from the resist defect portion;
removing the resist film after the etching;
forming a second electrode film at the surface of the first electrode film after the removal of the resist film, thereby forming a surface electrode constituted by the first electrode film and the second electrode film; and
patterning the surface electrode.

2. The method of manufacturing the semiconductor device according to claim 1, wherein the etching includes converting the convex defect into a concave defect.

3. The method of manufacturing the semiconductor device according to claim 1, wherein the etching includes converting the convex defect into a convex portion having a height that is lower than a height of the convex defect.

4. The method of manufacturing the semiconductor device according to claim 1, wherein a thickness of the resist film is in a range of 2.6 μm to 3.2 μm.

5. The method of manufacturing the semiconductor device according to claim 4, wherein the thickness of the resist film is not more than 3.0 μm.

6. The method of manufacturing the semiconductor device according to claim 1, wherein
the surface of first electrode film further has a flat portion, and
a height from the flat portion to a top of the convex defect is at least 4 μm.

7. The method of manufacturing the semiconductor device according to claim 1, wherein a thickness of the first electrode film is in a range of 10% to 90% of a thickness of the surface electrode.

8. The method of manufacturing the semiconductor device according to claim 7, wherein the thickness of the first electrode film is 50% of the thickness of the surface electrode.

9. The method of manufacturing the semiconductor device according to claim 1, wherein a thickness of the surface electrode is in a range of 4 μm to 6 μm.

10. The method of manufacturing the semiconductor device according to claim 1, wherein the surface electrode contains aluminum as a main constituent.

11. The method of manufacturing the semiconductor device according to claim 1, wherein the etching is wet etching.
